(19) United States
(12) Patent Application Publication
(10) Pub. No.: US 2025/0141191 A1
(43) Pub. Date: May 1, 2025

(54) SEMICONDUCTOR GREEN LASERS

(71) Applicant: ANHUI GAN SEMICONDUCTOR CO., LTD., Lu'an (CN)

(72) Inventors: Jinjian ZHENG, Lu'an (CN); Shuiqing LI, Lu'an (CN); Xin CAI, Lu'an (CN); Wanjun CHEN, Lu'an (CN); Jiabin LAN, Lu'an (CN); Jiangyong ZHANG, Lu'an (CN)

(73) Assignee: ANHUI GAN SEMICONDUCTOR CO., LTD., Lu'an (CN)

(21) Appl. No.: 18/401,284

(22) Filed: Dec. 29, 2023

Related U.S. Application Data
(63) Continuation of application No. PCT/CN2023/135950, filed on Dec. 1, 2023.

(30) Foreign Application Priority Data
Oct. 25, 2023 (CN) 202311387385.7

(51) Int. Cl. H01S 5/343; H01S 5/34

(52) U.S. Cl. CPC H01S 5/34346; H01S 5/3407

(57) ABSTRACT

The present disclosure provides a semiconductor green laser. The semiconductor green laser, from bottom to top, comprising a substrate, a lower limiting layer, a lower waveguide layer, an active layer, an upper waveguide layer, and an upper limiting layer. The active layer is a quantum well composed of well layers and barrier layers. Each of the well layers includes any one of AlInGaN, AlInN, AlGaN, AlN, InN, InGaN, and GaN, or any combination thereof. Each of the barrier layers includes any one of AlInGaN, AlInN, AlGaN, AlN, InN, InGaN, and GaN, or any combination thereof. An electron effective mass of each of the well layers is less than an electron effective mass of each of the barrier layers. A spontaneous polarization coefficient of each of the well layers is less than a spontaneous polarization coefficient of each of the barrier layers.

### CROSS-REFERENCE TO RELATED APPLICATIONS

This application is a Continuation of International Application No. PCT/CN2023/135950, filed on Dec. 1, 2023, which claims priority to Chinese Patent Application No. 202311387385.7, filed on Oct. 25, 2023, the entire contents of which are incorporated herein by reference.

### TECHNICAL FIELD

The present disclosure relates to the technical field of semiconductor optoelectronic devices, and in particular, to a semiconductor green laser.

### BACKGROUND

A laser device is widely used in the fields of laser display, laser TVs, laser projectors, communication, medical, weapons, guidance, ranging, spectral analysis, cutting, precision welding, high-density optical storage, or the like. There are many types of laser devices classified in various ways, mainly including solid, gas, liquid, semiconductor, and dye types of laser devices. Compared with other types of laser devices, an all-solid-state semiconductor laser device has the advantages of small size, high efficiency, light weight, good stability, long service life, simple and compact structure, miniaturization, etc.

Major differences between the laser device and a nitride semiconductor light-emitting diode (LED) are illustrated as follows.

(1) A laser is generated by carriers undergoing excited radiation, a spectral full width at half maximum (FWHM) is small, a brightness is very high, and an output power of a single laser may be in a W level. However, light of the nitride semiconductor LED is generated by spontaneous radiation, and an output power of a single LED is in an mW level.

(2) A usage current density of the laser device reaches KA/cm², which is two orders of magnitude higher than that of the nitride LED, thus causing stronger electron leakage, more severe Auger recombination, a stronger polarization effect, and a more severe electron-hole mismatch, which leads to a more severe Droop effect in efficiency.

(3) The LED has spontaneous transition radiation from high-energy-level incoherent light to low-energy-level incoherent light without external action. However, the laser device is implemented by excited transition radiation, the induced photon energy is equal to a difference between the energy levels of the electron transition, resulting in identical coherent light of photons and induced photons.

(4) The principle is different. The LED is that under the action of an external voltage, electron holes jump to an active layer or a p-n junction to produce radiative recombination light. However, the laser device needs to meet the condition of excitation of an inversion distribution in an active region carrier before being excited. The excited radiation light oscillates back and forth in a resonant cavity to realize light amplification by propagating in a gain medium, so that a threshold condition is met, the gain is greater than the loss, and the laser light is ultimately output.

A nitride semiconductor laser device has the following problems.

(1) A p-type semiconductor has the problems that activation energy of a Mg acceptor is high, dissociation efficiency is low, a hole concentration is much lower than an electron concentration, a hole mobility is much smaller than an electron mobility, a quantum well polarization electric field enhances a hole injection barrier and holes overflow of an active layer, etc. Uneven and inefficient hole injection leads to severe asymmetry and mismatch of electrons and holes in a quantum well, electron leakage and carrier de-localization, more difficult hole transport in the quantum well, uneven carrier injection, and uneven gain. In addition, a laser gain spectrum is broadened and a peak gain is decreased, resulting in an increase in a laser threshold current and a decrease in a slope efficiency.

(2) An increase of the element In in the quantum well produces rise and strain in the element In, broadens the laser gain spectrum, and decreases the peak gain. InN bonding energy is low, high element In in InGaN in the growth process needs a relatively low temperature to ensure In recombination, but a low temperature growth condition may lead to low atomic mobility, a decrease in low temperature NH3 cleavage efficiency, and large InN and GaN miscibility gaps, resulting in high defect density inside the active layer, InN phase-separation bias, thermal degradation, component fluctuations, and poor crystal quality, which in turn leads to poor quantum well quality and interface quality, non-uniform broadening of laser spectrums and an increase in non-radiative recombination centers or optical catastrophes. If the element In in the quantum well is increased, the thermal stability may be worse, and a high-temperature p-type semiconductor and growth of a limiting layer may cause thermal degradation and lattice mismatch in the active layer, thereby lowering the quality of the active layer and the Interface quality, decreasing the radiation efficiency, and shortening the service life of the laser device, particularly a green laser device with a high element In, the InN phase separation, segregation, and fluctuation of the element in the active layer may be more serious, and the crystal quality and the interface quality may be worse.

(3) The lattice mismatch and large strain in the active layer may lead to a strong piezoelectric polarization effect, which generates a quantum-confined stark effect QCSE, an increase in a band order difference of a valence band of the laser device, a more difficult injection and transport of holes in the quantum well, a decrease in the overlap probability of a electron-hole wavefunction, non-uniform injection of carriers, non-uniform gain, and a decline in the peak gain, resulting in an increase in the threshold current and a decrease in the slope efficiency of the laser device, thereby restricting improvement of an electrical excitation gain of the laser device.

(4) A thickness of a lower limiting layer may be increased, which may reduce a refractive index of the limiting layer. However, the increased thickness of the lower limiting layer may limit regulating ranges of elements, which is prone to cracking, bending, quality degradation, or other problems. In addition, the optical field has a dissipation, and optical field modes may lead to a substrate to form standing waves, causing low suppression efficiency of the substrate modes, and the poor far-field pattern (FFP) quality of a far-field image.

(5) The usage current of the laser device is high, and the current density is high, which generates large amount of heat, and the device has poor heat dissipation and poor temperature characteristics, causing the thermal mismatch between the epitaxial layers of the semiconductor, thereby leading to problems such as a rise in the threshold current and a decrease in output optical power and slope efficiency.

(6) Thermal loss: the Stokes shift loss formed by a photon energy difference between pump light and oscillating light may be converted into heat, and the energy loss of which a coupling rate between a pump energy level and a laser energy level is not 1 may be converted into heat. The heat may produce a large amount of waste heat, so that a temperature of the laser device is not uniformly distributed, resulting in thermal expansion and uneven distribution of thermal stress, temperature quenching, breakage of the laser device, a thermal lens effect and a stress birefringence effect. In addition, thermal lensing may produce a lens-like phenomenon in space, while the stress birefringence effect may change a polarization state of an incident light, thereby depolarizing and distorting a laser beam.

Therefore, it is desirable to provide a semiconductor green laser capable of effectively remedying the deficiencies in the prior arts.

### SUMMARY

One or more embodiments of the present disclosure provide a semiconductor green laser. The semiconductor green laser, from bottom to top, may comprise a substrate, a lower limiting layer, a lower waveguide layer, an active layer, an upper waveguide layer, and an upper limiting layer. The active layer may be a quantum well composed of well layers and barrier layers, and a period of the quantum well may be denoted as z, wherein 1≤z≤3. Each of the well layers may include any one of AlInGaN, AlInN, AlGaN, AlN, InN, InGaN, and GaN, or any combination thereof. A thickness of each of the well layers may be denoted as p, wherein 5 Å≤p≤100 Å. Each of the barrier layers may include any one of AlInGaN, AlInN, AlGaN, AlN, InN, InGaN, and GaN, or any combination thereof. A thickness of each of the barrier layers may be denoted as q, wherein 10 Å≤q≤200 Å. An electron effective mass of each of the well layers may be less than an electron effective mass of each of the barrier layers. A spontaneous polarization coefficient of each of the well layers may be less than a spontaneous polarization coefficient of each of the barrier layers. A band gap of each of the well layers may be less than a band gap of each of the barrier layers.

In some embodiments, the active layer may include a first active layer and a second active layer. An electron effective mass of the first active layer may have an inverted U-shaped distribution. An electron effective mass of the second active layer may have a W-shaped distribution. A spontaneous polarization coefficient of the first active layer may have an inverted U-shaped distribution. A spontaneous polarization coefficient of the second active layer may have a W-shaped distribution. A band gap of the first active layer may have an inverted U-shaped distribution. A band gap of the second active layer may have a W-shaped distribution.

In some embodiments, the electron effective mass of the first active layer may have a curvilinear distribution of a first function, the first function being denoted as y=Ax²+Bx+C (A<0). The spontaneous polarization coefficient of the first active layer may have a curvilinear distribution of a second function, the second function being denoted as y=Dx²+Ex+F (D<0). The band gap of the first active layer may have a curvilinear distribution of a third function, the third function being denoted as y=Jx²+Kx+K (J<0), wherein −500<A≤J≤D<0, and A, B, C, D, E, F, J, and K may be constants.

In some embodiments, the electron effective mass of the second active layer may have a curvilinear distribution of a fourth function. The fourth function may be denoted as y=Lcos(Mx+N). The spontaneous polarization coefficient of the second active layer may have a curvilinear distribution of a fifth function. The fifth function may be denoted as y=Pcos(Qx+O). The band gap of the second active layer may have a curvilinear distribution of a sixth function. The sixth function may be denoted as y=Rcos(Sx+T), wherein P≤R≤L, and L, M, N, P, Q, O, R, S, T may be constants.

In some embodiments, the electron effective mass of the first active layer may be denoted as a, an electron effective mass of each of well layers of the second active layer may be denoted as b, and an electron effective mass of each of barrier layers of the second active layer may be denoted as c, wherein 0.05 mₑ≤b≤c≤a≤0.2 mₑ. The spontaneous polarization coefficient of the first active layer may be denoted as d, a spontaneous polarization coefficient of each of the well layers of the second active layer may be denoted as e, and a spontaneous polarization coefficient of each of the barrier layers of the second active layer may be denoted as f, wherein −0.05 C/m²≤e≤f≤d≤−0.02 C/m². The band gap of the first active layer may be denoted as g, a band gap of each of the well layers of the second active layer may be denoted as h, and a band gap of each of the barrier layers of the second active layer may be denoted as i, wherein 0.5eV≤h≤i≤g≤3.5 eV.

In some embodiments, an element concentration ratio In/Al of an element In to an element Al of the first active layer may have a U-shaped distribution. An element concentration ratio In/Al of an element In to an element Al of the second active layer may have an M-shaped distribution. An element concentration ratio Si/H of an element Si to an element H of the first active layer may have an inverted U-shaped distribution. An element a concentration of an element H of the second active layer may have a linear distribution.

In some embodiments, the element concentration ratio In/Al of the element In to the element Al of the first active layer may be within a range of 10-100. The element concentration ratio In/Al of the element In to the element Al of the second active layer may be within a range of 1 E4-5E5. An element concentration ratio In/Al of the second active layer to the first active layer may be within a range of 1 E3-5E4.

In some embodiments, a descending angle of an element intensity of the element In in a direction from the second active layer to the first active layer may be denoted as α, wherein 45°≤α≤90°. A descending angle of an element intensity of the element In in a direction from the lower waveguide layer to the first active layer may be denoted as β, wherein 45°≤β≤90°. A descending angle of an element concentration ratio In/Al of an element In to an element Al in a direction from the second active layer to the first active layer may be denoted as γ, wherein 35°≤γ≤90°. A descending angle of an element concentration ratio In/Al of an element In to an element Al in a direction from the lower waveguide layer to the first active layer may be denoted as θ, wherein 35°≤θ≤90°. 35°≤γ≤θ≤α≤β≤90°.

In some embodiments, the lower limiting layer may include any one of AlInGaN, AlInN, AlGaN, AlN, InN, InGaN, and GaN, or any combination thereof. The lower limiting layer may include a first lower limiting layer, a second lower limiting layer, a third lower limiting layer, a fourth lower limiting layer, and a fifth lower limiting layer.

In some embodiments, a thermal expansion coefficient of the first lower limiting layer may be denoted as a1. A thermal expansion coefficient of the second lower limiting layer may be denoted as a2. A thermal expansion coefficient of the third lower limiting layer may be denoted as a3. A thermal expansion coefficient of the fourth lower limiting layer may be denoted as a4. A thermal expansion coefficient of the fifth lower limiting layer may be denoted as a5. A thermal expansion coefficient of the lower waveguide layer may be denoted as b. A thermal expansion coefficient of the active layer may be denoted as c. A thermal expansion coefficient of the upper waveguide layer may be denoted as d. A thermal expansion coefficient of the upper limiting layer may be denoted as f. A gradient of a thermal expansion coefficient of the semiconductor green laser may satisfy a relationship of: 2.5(10⁻⁶/K)≤c≤d≤a3≤b≤a5≤a1≤f≤a2≤a4≤6.5(10⁻⁶/K).

In some embodiments, a dielectric constant of the first lower limiting layer may be denoted as g1. A dielectric constant of the second lower limiting layer may be denoted as g2. A dielectric constant of the third lower limiting layer may be denoted as g3. A dielectric constant of the fourth lower limiting layer may be denoted as g4. A dielectric constant of the fifth lower limiting layer may be denoted as g5. A dielectric constant of the lower waveguide layer may be denoted as h. A dielectric constant of the active layer may be denoted as i. A dielectric constant of the upper waveguide layer may be denoted as j. A dielectric constant of the upper limiting layer may be denoted as k. A gradient of a dielectric constant of the semiconductor green laser may satisfy a relationship of: 8≤g4≤g2≤k≤g1≤g5≤h≤g3≤j≤i≤12.

In some embodiments, an elastic coefficient C₃₃ of the first lower limiting layer may be denoted as s1. An elastic coefficient C₃₃ of the second lower limiting layer may be denoted as s2. An elastic coefficient C₃₃ of the third lower limiting layer may be denoted as s3. An elastic coefficient C₃₃ of the fourth lower limiting layer may be denoted as s4. An elastic coefficient C₃₃ of the fifth lower limiting layer may be denoted as s5, an elastic coefficient C₃₃ of the third lower limiting layer is denoted as S3. An elastic coefficient C₃₃ of the lower waveguide layer may be denoted as t. An elastic coefficient C₃₃ of the active layer may be denoted as u. An elastic coefficient C₃₃ of the upper waveguide layer may be denoted as v. An elastic coefficient C₃₃ of the upper limiting layer may be denoted as w. A gradient of an elastic coefficient C₃₃ of the semiconductor green laser may satisfy a relationship of: 200 GPa≤u≤v≤s3≤t≤s4≤s2≤w≤s1≤s5≤450 GPa.

In some embodiments, a thermal expansion coefficient of the third lower limiting layer may have a curvilinear distribution of a seventh function, the seventh function being denoted as y=x/sinx. An elastic coefficient of the third lower limiting layer may have a curvilinear distribution of an eighth function, the eighth function being denoted as y=x/sinx. A dielectric constant of the third lower limiting layer may have a curvilinear distribution of a ninth function, the ninth function being denoted as y=Vx²+Ux+W(V<0), wherein V, U and W may be constants.

In some embodiments, the lower waveguide layer may include any one of AlInGaN, AlInN, AlGaN, InGaN, InN, and GaN, or any combination thereof. A thickness of the lower waveguide layer may be within a range of 10 Å-9000 Å. The upper waveguide layer may include any one of AlInGaN, AlInN, AlGaN, InGaN, InN, and GaN, or any combination thereof. A thickness of the upper waveguide layer may be within a range of 10 Å-9000 Å. The upper limiting layer may include any one of AlInGaN, AlInN, AlN, AlGaN, InGaN, and GaN, or any combination thereof. A thickness of the upper limiting layer may be within a range of 10 Å-8000 Å. The lower limiting layer may include any one of a sapphire, silicon, Ge, SiC, AlN, GaN, GaAs, InP, Mo, TiW, Cu, a sapphire/SiO₂ composite substrate, a sapphire/AlN composite substrate, a diamond, sapphire/SiNₓ, a sapphire/SiNₓ/SiO₂ composite substrate, a sapphire/SiO₂/SiNₓ composite substrate, and a magnesium aluminate spinel MgAl₂O₄, MgO, ZnO, ZrB₂, LiAlO₂, and LiGaO₂ composite substrate.

One or more embodiments of the present disclosure may have the following beneficial effects.

The active layer of the embodiments of the present disclosure is the periodic structure composed of the well layers and the barrier layers. The electron effective mass of each of the well layers of the active layer may be less than the electron effective mass of each of the barrier layers of the active layer. The spontaneous polarization coefficient of each of the well layers may be less than the spontaneous polarization coefficient of each of the barrier layers. The band gap of each of the well layers may be less than the band gap of each of the barrier layers. The ratio of the element In to the element Al of the first active layer has the U-shaped distribution, and the ratio of the element In to the element Al of the second active layer has the M-shaped distribution, thereby reducing a hole injection barrier, enhancing the efficiency of hole injection into the active layer, improving carrier localization, and enhancing the electron-hole recombination efficiency of the active layer. In addition, the InN phase separation, segregation, and component fluctuation in a high In-component green laser can be suppressed, thereby improving the crystal quality and the interface quality of the active layer, reducing defects and non-radiative recombination centers, and enhancing the slope efficiency of the green laser.

According to the embodiments of the present disclosure, the quantum-confined Stark effect is alleviated by suppression, so that the piezoelectric polarization effect is reduced, the energy band tilt of the active layer is reduced, the order of the valence band is reduced, the efficiency and the transport capacity of hole injection into the active layer are improved, the carrier uniformity and the laser excitation gain uniformity of the laser are improved, and the optical power, the excitation gain, and the slope efficiency of the laser are improved.

The lower limiting layer in the embodiments described herein has a thermal expansion coefficient gradient, a dielectric constant gradient, and an elasticity coefficient C₃₃ gradient. The thermal expansion coefficient gradient and the elasticity coefficient gradient are configured to enhance the uniformity of a temperature distribution in the laser, reduce the thermal expansion coefficient and the uniformity of a thermal stress distribution, suppress temperature quenching, breakage of the laser, the thermal lens effect, and the stress birefringence effect, thereby improving the depolarization and distortion of the laser beam, and enhancing the beam quality factor and the focusing spot resolution of the laser. The dielectric constant gradient and elasticity coefficient gradient can improve thermal mismatch, reduce threshold current, improve optical power output and the slope efficiency, and also resolve the problem of optical field dissipation, thereby suppressing leakage of optical field modes to the substrate, and enhancing the FFP quality of the far-field image.

### BRIEF DESCRIPTION OF THE DRAWINGS

The present disclosure will be further illustrated by way of exemplary embodiments, which will be described in detail by means of the accompanying drawings. These embodiments are not limiting. In these embodiments, the same numbering indicates the same structure, wherein:

FIG. 1 is a schematic diagram illustrating a structure of a semiconductor green laser according to some embodiments of the present disclosure;

FIG. 2 is a secondary ion mass spectroscopy (SIMS) illustrating a structure of a semiconductor green laser according to some embodiments of the present disclosure;

FIG. 3 is an SIMS illustrating a structure of a semiconductor green laser according to some embodiments of the present disclosure;

FIG. 4 is a transmission electron microscope (TEM) diagram illustrating an active layer of a semiconductor green laser according to some embodiments of the present disclosure;

FIG. 5 is a TEM diagram illustrating an upper waveguide layer of a semiconductor green laser according to some embodiments of the present disclosure;

FIG. 6 is a TEM diagram illustrating an upper limiting layer of a semiconductor green laser according to some embodiments of the present disclosure;

FIG. 7 is an SIMS (identifying an angle of variation) illustrating a semiconductor green laser according to some embodiments of the present disclosure;

FIG. 8 an SIMS illustrating a structure of a lower limiting layer of a semiconductor green laser according to some embodiments of the present disclosure; and

FIG. 9 is a TEM diagram illustrating a lower limiting layer of a semiconductor green laser according to some embodiments of the present disclosure.

Reference signs: 100: substrate; 101: lower limiting layer; 102: lower waveguide layer; 103: active layer; 103a: first active layer; 103b: second active layer; 104: upper waveguide layer; 105: upper limiting layer.

### DETAILED DESCRIPTION

In order to more clearly illustrate the technical solutions of the embodiments of the present disclosure, the following briefly introduces the drawings that need to be used in the description of the embodiments. Apparently, the accompanying drawings in the following description are only some examples or embodiments of the present disclosure, and those skilled in the art can also apply the present disclosure to other similar scenarios according to the drawings without creative efforts. Unless obviously obtained from the context or the context illustrates otherwise, the same numeral in the drawings refers to the same structure or operation.

It should be understood that “system”, “device”, “unit” and/or “module” as used herein is a method for distinguishing different components, elements, parts, portions or assemblies of different levels. However, the words may be replaced by other expressions if other words can achieve the same purpose.

As indicated in the disclosure and claims, the terms “a”, “an”, and/or “the” are not specific to the singular form and may include the plural form unless the context clearly indicates an exception. Generally speaking, the terms “comprising” and “including” only suggest the inclusion of clearly identified steps and elements, and these steps and elements do not constitute an exclusive list, and the method or device may also contain other steps or elements.

The flowchart is used in the present disclosure to illustrate the operations performed by the system according to the embodiments of the present disclosure. It should be understood that the preceding or following operations are not necessarily performed in the exact order. Instead, various steps may be processed in reverse order or simultaneously. Meanwhile, other operations may be added to these procedures, or a certain step or steps may be removed from these procedures.

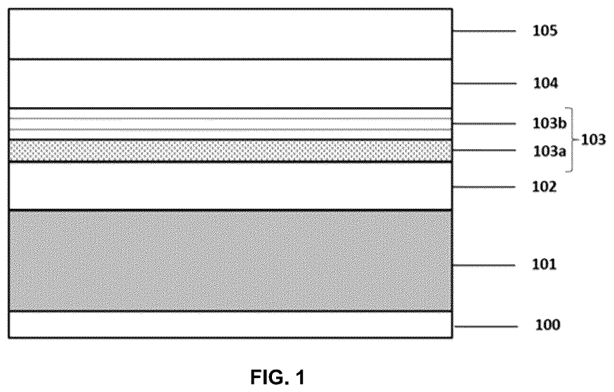

FIG. 1 is a schematic diagram illustrating a structure of a semiconductor green laser according to some embodiments of the present disclosure.

In some embodiments, the semiconductor green laser, from bottom to top, may comprise a substrate 100, a lower limiting layer 101, a lower waveguide layer 102, an active layer 103, an upper waveguide layer 104, and an upper limiting layer 105.

In some embodiments, the lower limiting layer 101 may be fabricated on the substrate 100. The lower waveguide layer 102 may be fabricated on the lower limiting layer 101. The active layer 103 may be fabricated on the lower waveguide layer 102. The upper waveguide layer 104 may be fabricated on the active layer 103. The upper limiting layer 105 may be fabricated on the upper waveguide layer 104.

The substrate 100 may be a main base of a laser. The substrate 100 may be configured to implement growth of each layer the semiconductor laser. In some embodiments, the substrate 100 may include a semiconductor substrate or a composite substrate. In some embodiments, the substrate 100 may include any one of a sapphire, silicon, Ge, SiC, AlN, GaN, GaAs, InP, Mo, TiW, Cu, a sapphire/SiO₂ composite substrate, a sapphire/AlN composite substrate, a diamond, sapphire/SiNₓ, a sapphire/SiNₓ/SiO₂ composite substrate, a sapphire/SiO₂/SiNₓ composite substrate, a magnesium aluminum spinel MgAl₂O₄, MgO, ZnO, ZrB2, LiAlO₂, and a LiGaO₂ composite substrate. For example, the substrate 100 may include the silicon.

The lower limiting layer 101 and the upper limiting layer 105 may be configured to effectively impede electron diffusion and drift, and limit the expansion of transverse modes of a light field to the limiting layer, thereby reducing light loss, lowering the potential barrier, and reducing the voltage loss. In some embodiments, the lower limiting layer 101 may include any one of AlInGaN, AlInN, AlN, AlGaN, and GaN, or any combination thereof. A thickness of the lower limiting layer 101 may be within a range of 10 Å-90,000 Å. For example, the thickness of the lower limiting layer 101 may be 10 Å, 100 Å, 1,000 Å, 10,000 Å, 90,000 Å, or the like.

In some embodiments, the upper limiting layer 105 may include any one of AlInGaN, AlInN, AlN, AlGaN, InGaN, and GaN, or any combination thereof. A thickness of the upper limiting layer 105 may be within a range of 10 Å-8000 Å. For example, the thickness of the upper limiting layer 105 may be 10 Å, 100 Å, 1,000 Å, 8000 Å, or the like. The upper limiting layer 105 and the lower limiting layer 101 may include same or different materials. For example, the upper limiting layer 105 and the lower limiting layer 101 may include GaN.

The lower waveguide layer 102 and the upper waveguide layer 104 may have a high refractive index that allows a portion of the light field to expand from a main waveguide to the waveguide layer, thereby expanding near-field spots and reducing a far-field divergence angle of the laser. In some embodiments, the lower waveguide layer 102 may include any one of AlInGaN, AlInN, AlGaN, InGaN, InN, and GaN, or any combination thereof. A thickness of the lower waveguide layer 102 may be within a range of 10 Å ˜9000 Å. For example, the thickness of the lower waveguide layer 102 may be 10 Å, 100 Å, 1,000 Å, 9000 Å, or the like.

In some embodiments, the upper waveguide layer 104 may include any one of AlInGaN, AlInN, AlGaN, InGaN, InN, and GaN, or any combination thereof. A thickness of the upper waveguide layer 104 may be within a range of 10 Å-9000 Å. For example, the thickness of the upper waveguide layer 104 may be 10 Å, 100 Å, 1,000 Å, 9000 Å, or the like. The lower waveguide layer 102 and the upper waveguide layer 104 may include same or different materials. For example, both the lower waveguide layer 102 and the upper waveguide layer 104 may include InN.

In the embodiments of the present disclosure, the laser can be formed by selecting the substrate 100, the lower limiting layer 101, the lower waveguide layer 102, the upper waveguide layer 104, and the upper limiting layer 105 including suitable materials, and the thickness of each layer can be limited within a certain range, thereby ensuring the quality of the laser to a certain extent.

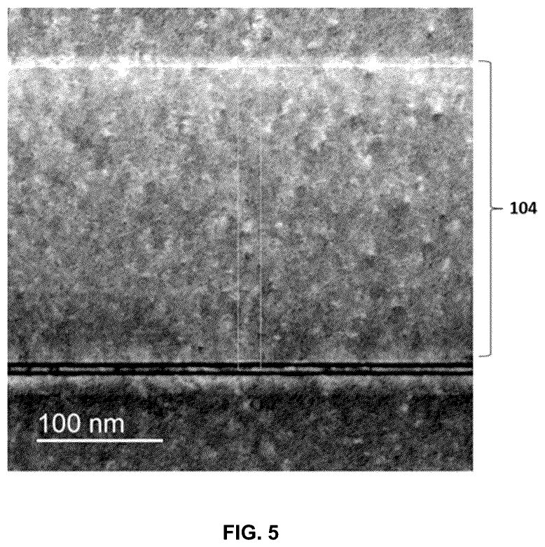

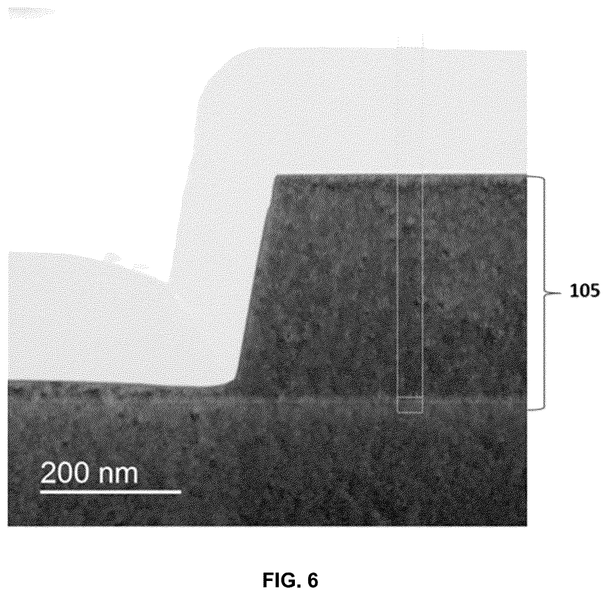

FIG. 5 a TEM diagram illustrating an upper waveguide layer of a semiconductor green laser according to some embodiments of the present disclosure, and a resolution is 100 nm. FIG. 6 is a TEM diagram illustrating an upper waveguide layer of a semiconductor green laser according to some embodiments of the present disclosure, and a resolution is 200 nm.

The active layer 103 is a light-emitting region of the laser. Electrons and holes entering the active layer may be confined within the active layer due to a heterojunction barrier, resulting in an inversion of a particle count distribution. Spontaneous radiation light may be generated when the particles of which the particle count distribution is reversed in the active layer recombine with the holes.

In some embodiments, the active layer 103 may be a quantum well composed of well layers and barrier layers. The quantum well is a potential well that restricts particles to a two-dimensional plane with a discrete energy level while allowing them to move freely in a three-dimensional (3D) space. A quantum well structure of a semiconductor is a composite structure formed by alternating two semiconductor materials. The period of the quantum well is a count of the quantum well structure and may be denoted as z, wherein 1≤z≤3. Merely by way of example, when the period z of the quantum well structure is 1, the active layer 103 may be a single quantum well structure. When the period z of the quantum well structure is 2 or 3, the active layer 103 may be a multi-quantum well structure. The quantum well may be created by periodically stacking the well layers and the barrier layers. Under the effect of an applied electric field, electrons in the quantum well may make transitions from a low-energy band material (e.g., the barrier layers) to a high-energy band material (e.g., the well layers), releasing energy in the form of photons to generate laser light.

In some embodiments, each of the well layers of the active layer 103 may include any one of AlInGaN, AlInN, AlGaN, AlN, InN, InGaN, and GaN, or any combination thereof. For example, each of the well layers of the active layer 103 may include AlInGaN.

In some embodiments, each of the barrier layers of the active layer 103 may include any one of AlInGaN, AlInN, AlGaN, AlN, InN, InGaN, and GaN, or any combination thereof. For example, each of the barrier layers of the active layer 103 may include AlGaN.

In some embodiments, parameters of the well layers and parameters of the barrier layers may be different in, such as a thickness, an electron effective mass, a spontaneous polarization coefficient, a band gap, or the like.

The thickness of each of the well layers and the thickness of each of the barrier layers of the quantum well may have an effect on the performance of the laser. The thickness of each of the well layers may be denoted as p and the thickness of each of the barrier layers may be denoted as q. In some embodiments, p satisfies that 5 Å≤p≤100 Å and q satisfies that 10 Å≤q≤200 Å. For example, the thickness p of each of the well layers may be 5 Å, 10 Å, 20 Å, 100 Å, etc., and the thickness q of each of the barrier layers may be 5 Å, 10 Å, 20 Å, 100 Å, etc.

In some embodiments, the electron effective mass of each of the well layers of the active layer 103 may be less than the electron effective mass of each of the barrier layers of the active layer 103. The spontaneous polarization coefficient of each of the well layers may be less than the spontaneous polarization coefficient of each of the barrier layers. The band gap of each of the well layers may be less than the band gap of each of the barrier layers.

The electron effective mass is a physical quantity used to describe the electrons in a semiconductor under the effect of an external force. The electron effective mass is an important fundamental parameter that affects measurable properties of solids. Spontaneous polarization refers to a phenomenon that the positive and negative charge centers of certain regions within a crystal do not coincide and exhibit an electric dipole moment in the absence of an external electric field. The spontaneous polarization coefficient may be used to measure a degree of spontaneous polarization. The band gap is a width of a bandgap. To become a free electron or a hole, the bound electron needs to acquire enough energy to transition from the valence band to the conduction band, and a minimum energy required for the transition is the band gap. An energy band in which free electrons exist is referred to as a conduction band, and an energy band in which free holes exist is referred to as a valence band. The valence band and the conduction band may conduct electricity.

In some embodiments of the present disclosure, the active layer 103 may be the periodic structure composed of the well layers and the barrier layers. The electron effective mass of each of the well layers of the active layer 103 may be less than the electron effective mass of each of the barrier layers of the active layer 103. The spontaneous polarization coefficient of each of the well layers may be less than the spontaneous polarization coefficient of each of the barrier layers. The band gap of each of the well layers may be less than the band gap of each of the barrier layers, thereby suppressing the quantum-confined Stark effect, reducing the piezoelectric polarization effect, decreasing the energy band tilt of the active layer, lowering the order of the valence band, enhancing the efficiency and transport capacity of hole injection into the active layer, improving the carrier uniformity and the laser excitation gain uniformity of the laser, and improving the optical power, the excitation gain, and the slope efficiency of the laser.

In some embodiments, the active layer 103 may include a first active layer 103a and a second active layer 103b, and the period of the quantum well may be 2.

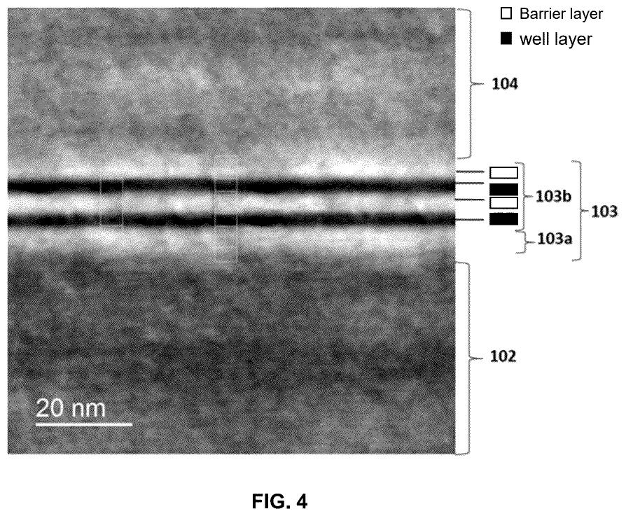

FIG. 4 is a TEM diagram illustrating an active layer of a semiconductor green laser according to some embodiments of the present disclosure, and a resolution is 20 nm. As illustrated in FIG. 4, the active layer 103 located between the upper waveguide layer 104 and the lower waveguide layer 102, from top to bottom, may include a barrier layer of the second active layer 103b, a well layer of the second active layer 103b, a barrier layer of the first active layer 103a, and a well layer of the first active layer 103a.

In some embodiments, an electron effective mass of the first active layer 103a may have an inverted U-shaped distribution. An electron effective mass of the second active layer 103b may have a W-shaped distribution. A spontaneous polarization coefficient of the first active layer 103a may have an inverted U-shaped distribution. A spontaneous polarization coefficient of the second active layer 103b may have a W-shaped distribution. A band gap of the first active layer 103a may have an inverted U-shaped distribution. A band gap of the second active layer 103b may have a W-shaped distribution.

In some embodiments, the electron effective mass of the first active layer 103a may have a curvilinear distribution of a first function, and the first function may be denoted as y=Ax²+Bx+C (A<0). The spontaneous polarization coefficient of the first active layer 103a may have a curvilinear distribution of a second function, and the second function may be denoted as y=Dx²+Ex+F (D<0). The band gap of the first active layer 103a may have a curvilinear distribution of a third function, and the third function may be denoted as y=Jx²+Kx+K (J<0), wherein −500<A≤J≤D<0, and A, B, C, D, E, F, J, and K may be constants.

In some embodiments, the electron effective mass of the second active layer 103b may have a curvilinear distribution of a fourth function, and the fourth function may be denoted as y=Lcos(Mx+N). The spontaneous polarization coefficient of the second active layer 103b may have a curvilinear distribution of a fifth function, and the fifth function may be denoted as y=Pcos(Qx+O). The band gap of the second active layer 103b may have a curvilinear distribution of a sixth function, and the sixth function may be denoted as y=Rcos(Sx+T), wherein P≤R≤L, x may be a variable, and L, M, N, P, Q, O, R, S, and T may be constants.

In some embodiments, the electron effective mass of the first active layer 103a may be denoted as a. The electron effective mass of each of the well layers of the second active layer 103b may be denoted as b. The electron effective mass of each of the barrier layers of the second active layer 103b may be denoted as c, wherein 0.05 mₑ≤b≤c≤a≤0.2 mₑ. The spontaneous polarization coefficient of the first active layer 103a may be denoted as d. The spontaneous polarization coefficient of each of the well layers of the second active layer 103b may be denoted as e. The spontaneous polarization coefficient of each of the barrier layers of the second active layer 103b may be denoted as f, wherein −0.05 C/m²≤e≤f≤d≤−0.02 C/m². The band gap of the first active layer 103a may be denoted as g. The band gap of each of the well layers of the second active layer 103b may be denoted as h. The band gap of each of the barrier layers of the second active layer 103b may be denoted as i, wherein 0.5 eV≤h≤i≤g≤3.5 eV. For example, a may be 0.15 mₑ, c may be 0.10 mₑ, b may be 0.05 mₑ, d may be −0.02 C/m², e may be −0.04 C/m², f may be −0.03 C/m², g may be 3.5 eV, h may be 0.5 eV, and i may be 1.5 eV.

In some embodiments, the active layer 103 may include the first active layer 103a and the second active layer 103b. An element concentration ratio In/Al of an element In to an element Al of the first active layer 103a may have a U-shaped distribution. An element concentration ratio In/Al of an element In to an element Al of the second active layer 103b may have an M-shaped distribution. An element concentration ratio Si/H of an element Si to an element H of the first active layer 103a may have an inverted U-shaped distribution. An element concentration ratio Si/H of an element Si to an element H of the second active layer 103b may have a linear distribution.

In some embodiments of the present disclosure, the element concentration ratio In/Al of the element In to the element Al of the first active layer 103a may have the U-shaped distribution, and the element concentration ratio In/Al of the element In to the element Al of the second active layer 103b may have the M-shaped distribution, so that the hole injection barrier may be reduced, the efficiency of hole injection into the active layer may be enhanced, the carrier localization effect may be enhanced, and the electron-hole recombination efficiency of the active layer may be enhanced. Meanwhile, the phase separation, segregation, and component fluctuation of the green laser having a high In component may be suppressed, thereby further enhancing the crystal quality and the interface quality of the active layer, reducing defects and non-radiative composite centers, and improving the slope efficiency of the green light laser.

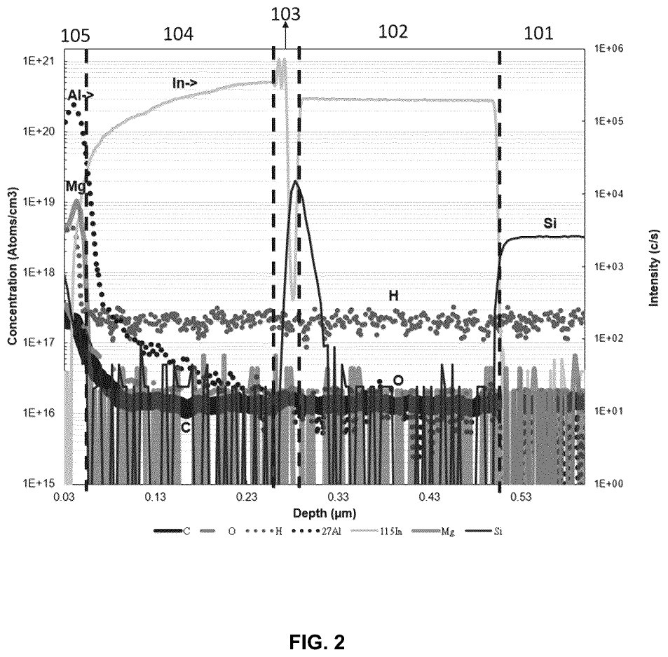

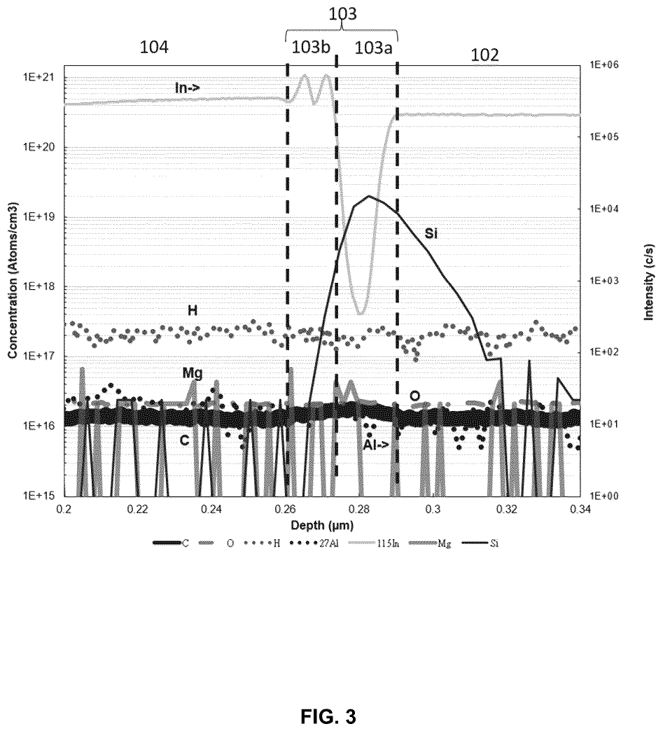

FIGS. 2-3 are an SIMS illustrating a structure of a semiconductor green laser according to some embodiments of the present disclosure. According to an SIMS test, a distribution of concentrations of elements in different layers may be observed. As illustrated in FIG. 2, a horizontal coordinate is a depth of the semiconductor laser, and may represent, from left to right, the upper limiting layer 105, the upper waveguide layer 104, the active layer 103, the lower waveguide layer 102, and the lower limiting layer 101. A left vertical coordinate represents the concentrations of the element, and a right vertical coordinate represents densities of the elements. In FIG. 3, the active layer 103 is further divided into the first active layer 103a and the second active layer 103b.

In some embodiments, the element concentration ratio In/Al of the element In to the element Al of the first active layer 103a may be within a range of 10-100. The element concentration ratio In/Al of the element In to the element Al of the second active layer 103b may be within a range of 1 E4-5E5. An element concentration In/Al of the second active layer 103b to the first active layer 103a may be within a range of 1 E3-5E4.

As illustrated in FIG. 3, the element In of the first active layer 103a may have an inverted V-shaped distribution, and the element In of the second active layer 103b may have an M-shaped distribution.

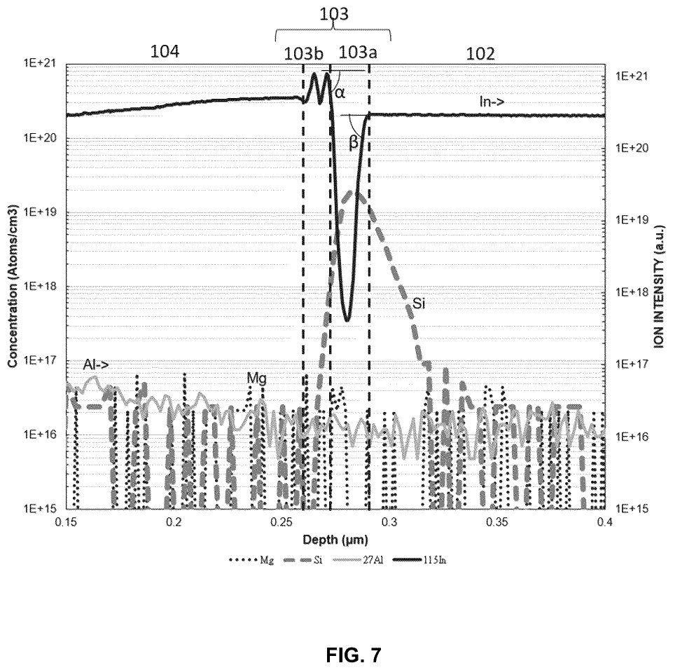

FIG. 7 is an SIMS (identifying an angle of variation) illustrating a semiconductor laser according to some embodiments of the present disclosure. A horizontal coordinate in FIG. 7 is a depth of the semiconductor laser, and may represent, from left to right, the upper waveguide layer 104, the second active layer 103b, the first active layer 103a, and the lower waveguide layer 102. A left vertical coordinate represents concentrations of the elements, and a right vertical coordinate represents densities of the elements. As illustrated in FIG. 7, a descending angle of an element intensity of an element In in a direction from the second active layer 103b to the first active layer 103a may be denoted as α. A descending angle of an element intensity of an element In in a direction from the lower waveguide layer 102 to the first active layer 103a may be denoted as β. In some embodiments, α satisfies that 45°≤α≤90° and β satisfies that 45°≤β≤90°. For example, α may be 45°, 60°, 90°, etc., and β may be 45°, 60°, 90°, etc.

In some embodiments, a descending angle of an element concentration ratio In/Al of an element In to an element Al in a direction from the second active layer 103b to the first active layer 103a may be denoted as y, wherein 35°≤γ≤90°. A descending angle of an element concentration ratio In/Al of an element In to an element Al in a direction from the lower waveguide layer 102 to the first active layer 103a may be denoted as θ, wherein 35°≤θ≤90°, and 35°≤γ≤θ≤α≤β≤90°. For example, γ may be 35°, θ may be 45°, α may be 55°, and β may be 65°.

In some embodiments of the present disclosure, a value of the ratio of the concentration of the element and the descent angle may be limited to an interval range, so that the quantum-confined Stark effect can be alleviated, the piezoelectric polarization effect can be reduced, the energy band tilt of the active layer can be reduced, the order of the valence band can be reduced, and the efficiency and transport capacity of hole injection into the active layer can be enhanced, thereby enhancing the carrier uniformity and the laser excitation gain uniformity of the laser, and enhancing the laser excitation gain and the slope efficiency of the laser.

In some embodiments, the lower limiting layer 101 may include any one of AlInGaN, AlInN, AlGaN, AlN, InN, InGaN, and GaN, or any combination thereof. In some embodiments, the lower limiting layer 101 may include a first lower limiting layer, a second lower limiting layer, a third lower limiting layer, a fourth lower limiting layer, and a fifth lower limiting layer.

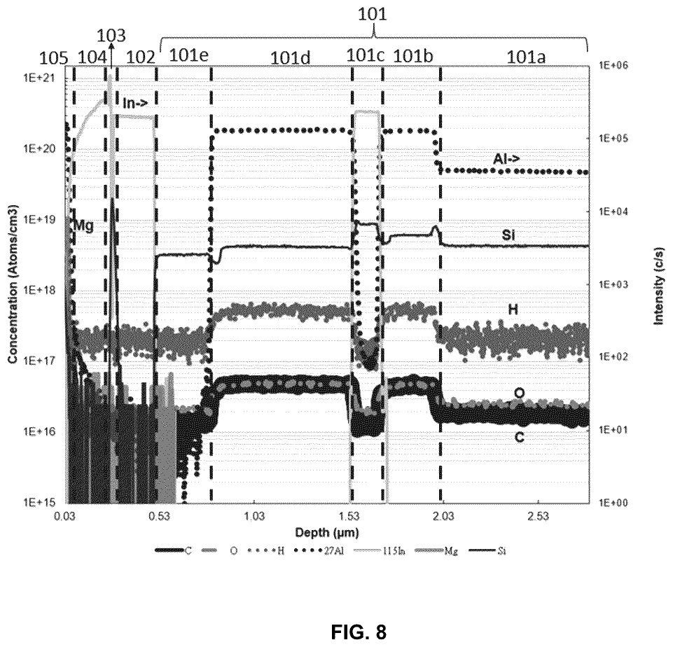

FIG. 8 is an SIMS illustrating a lower limiting layer of a semiconductor green laser according to some embodiments of the present disclosure. A horizontal coordinate in FIG. 8 is a depth of the semiconductor laser, and may represent, from left to right, the upper limiting layer 105, the upper waveguide layer 104, the active layer 103, the lower waveguide layer 102, a fifth lower limiting layer 101e, a fourth lower limiting layer 101d, a third lower limiting layer 101c, a second lower limiting layer 101b, and a first lower limiting layer 101a. A left vertical coordinate may represent concentrations of the elements, and a right vertical coordinate may represent densities of the elements. As illustrated in FIG. 8, distributions of elements Al, Si, H, O, and C of the first lower limiting layer 101a, the second lower limiting layer 101b, the third lower limiting layer 101c, the fourth lower limiting layer 101d, and the fifth lower limiting layer 101e may have significant variations. However, the variations in different elements may present a similar trend.

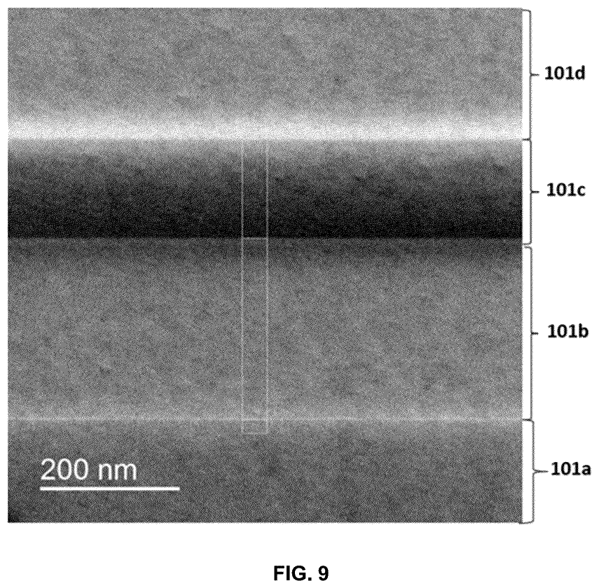

FIG. 9 is a TEM diagram illustrating a lower limiting layer of a semiconductor green laser according to some embodiments of the present disclosure, and a resolution is 200 nm. As illustrated in FIG. 9, the first lower limiting layer 101a, the second lower limiting layer 101b, the third lower limiting layer 101c, and the fourth lower limiting layer 101d may have significant variations in brightness, which may be caused by different material components of the layers.

In some embodiments, A thermal expansion coefficient of the first lower limiting layer may be denoted as a1. A thermal expansion coefficient of the second lower limiting layer may be denoted as a2. A thermal expansion coefficient of the third lower limiting layer may be denoted as a3. A thermal expansion coefficient of the fourth lower limiting layer may be denoted as a4. A thermal expansion coefficient of the fifth lower limiting layer may be denoted as a5. A thermal expansion coefficient of the lower waveguide layer 102 may be denoted as b. A thermal expansion coefficient of the active layer 103 may be denoted as c. A thermal expansion coefficient of the upper waveguide layer 104 may be denoted as d. A thermal expansion coefficient of the upper limiting layer 105 may be denoted as f. A gradient of a thermal expansion coefficient of the semiconductor green laser may satisfy a relationship of 2.5≤c≤d≤a3≤b≤a5≤a1≤f≤a2≤a4≤6.5 (10⁻⁶/K). The thermal expansion coefficient characterizes an extent of a variation in a length, an area, and a volume of an object when the object is heated.

In some embodiments, a dielectric constant of the first lower limiting layer may be denoted as g1. A dielectric constant of the second lower limiting layer may be denoted as g2. A dielectric constant of the third lower limiting layer may be denoted as g3. A dielectric constant of the fourth lower limiting layer may be denoted as g4. A dielectric constant of the fifth lower limiting layer may be denoted as g5. A dielectric constant of the lower waveguide layer 102 may be denoted as h. A dielectric constant of the active layer 103 may be denoted as i. A dielectric constant of the upper waveguide layer 104 may be denoted as j. A dielectric constant of the upper limiting layer 105 may be denoted as k. A gradient of a dielectric constant of the semiconductor green laser may satisfy a relationship of: 8≤g4≤g2≤k≤g1≤g5≤h≤g3≤j≤i≤12. The dielectric constant refers to a coefficient that characterizes an insulation capacity.

In some embodiments, an elasticity coefficient C₃₃ of the first lower limiting layer may be denoted as s1. An elasticity coefficient C₃₃ of the second lower limiting layer may be denoted as s2. An elasticity coefficient C₃₃ of the third lower limiting layer may be denoted as s3. An elasticity coefficient C₃₃ of the fourth lower limiting layer may be denoted as s4. An elasticity coefficient C₃₃ of the fifth lower limiting layer may be denoted as s5. An elasticity coefficient C₃₃ of the lower waveguide layer 102 may be denoted as t. An elasticity coefficient C₃₃ of the active layer 103 may be denoted as u. An elasticity coefficient C₃₃ of the upper waveguide layer 104 may be denoted as v. An elasticity coefficient C₃₃ of the upper limiting layer 105 may be denoted as w. A gradient of an elasticity coefficient C₃₃ of the semiconductor green laser may satisfy a relationship of 200 GPa≤u≤v≤s3≤t≤s4≤s2≤w≤s1≤s5s450 GPa. The elasticity coefficient refers to a ratio of a proportion of length deformation of a material to a proportion of variation in the applied force.

In some embodiments of the present disclosure, the lower limiting layer 101 may have a thermal expansion coefficient gradient, an dielectric constant gradient, and an elasticity coefficient C₃₃ gradient. The thermal expansion coefficient gradient and the elasticity coefficient gradient may be configured to enhance the uniformity of the temperature distribution of the laser, improve the uniformity of the thermal expansion coefficient and the thermal stress distribution, suppress temperature quenching, breakage of the laser, the thermal lens effect and the stress birefringence effect, improve depolarization and distortion of the laser device beam, enhance the beam quality factor of the laser, and improve the focusing spot resolution. The dielectric constant gradient and the elasticity coefficient gradient may improve the thermal mismatch, reduce the threshold current, enhance the optical power output and the slope efficiency, and also improve the problem of optical field dissipation, suppress leakage of optical field modes into the substrate, and improve the FFP quality of the far-field image.

In some embodiments, the thermal expansion coefficient of the third lower limiting layer may have a curvilinear distribution of a seventh function, and the seventh function may be denoted as y=x/sinx. The elasticity coefficient of the third lower limiting layer may have a curvilinear distribution of an eighth function, and the eighth function may be denoted as y=x/sinx. The dielectric constant of the third lower limiting layer may have a curvilinear distribution of a ninth function, and the ninth function may be denoted as y=Vx²+Ux+W(V<0), wherein V, U, and W may be constants.

To sum up, the laser described in the embodiments of the present disclosure have better beam quality factor, slope efficiency, threshold current density, optical power, and focusing spot resolution compared to conventional lasers. The beam quality factor is a parameter for evaluating the beam quality. The closer the beam quality factor is to 1, the better the beam quality and the stronger the focusing ability. The slope efficiency is a physical quantity that measures the output characteristics of the laser. The higher the slope efficiency, the higher the efficiency and the output power of the laser. The threshold current density is a physical quantity that characterizes the threshold excitation or oscillation achieved by electron injection into the semiconductor laser. Reducing the threshold current density may improve the conversion efficiency of the layer, reduce the thermal loss, and enhance the output power. The optical power is an amount of work done by light per unit time and represents the brightness or intensity of light. The focusing spot resolution represents a size of a spot based on a laser wavelength. The laser with a relatively short wavelength may provide a relatively small spot and a relatively high spatial resolution.

Specifically, compared with the conventional lasers, the laser described in the embodiments of the present disclosure has the beam quality factor that decreases from 6.7 to 3.97, a decrease of approximately 69%; the slope efficiency that increases from 0.55 W/A to 0.897 W/A, an increase of approximately 62%; the threshold current density that decreases from 3.6 KA/cm² to 0.95 KA/cm², a decrease of approximately 74%; the optical power that increases from 1.05 W to 1.49 W, an increase of approximately 42%; and the focusing spot resolution that decreases from being over 250 nm to be less than 20 nm, as illustrated in Table 1.

TABLE 1
Comparison of variations in laser

| | | Laser of the | |
|---|---|---|---|
| | Conventional | present | |
| Green Laser-Item | Laser | disclosure | Variation |
| Beam quality factor M² | 6.7 | 3.97 | 69% |
| Slope efficiency (W/A) | 0.55 | 0.89 | 62% |
| Threshold current density | 3.6 | 0.95 | −74% |
| (kA/cm²) | | | |
| Optical power (W) | 1.05 | 1.49 | 42% |
| Focusing spot resolution (nm) | >250 | <20 | |

The basic concept has been described above. Obviously, for those skilled in the art, the above detailed disclosure is only an example, and does not constitute a limitation to the present disclosure. Although not expressly stated here, those skilled in the art may make various modifications, improvements and corrections to the present disclosure. Such modifications, improvements and corrections are suggested in this disclosure, so such modifications, improvements and corrections still belong to the spirit and scope of the exemplary embodiments of the present disclosure.

Meanwhile, the present disclosure uses specific words to describe the embodiments of the present disclosure. For example, “one embodiment”, “an embodiment”, and/or “some embodiments” refer to a certain feature, structure or characteristic related to at least one embodiment of the present disclosure. Therefore, it should be emphasized and noted that references to “one embodiment” or “an embodiment” or “an alternative embodiment” two or more times in different places in the present disclosure do not necessarily refer to the same embodiment. In addition, certain features, structures or characteristics in one or more embodiments of the present disclosure may be properly combined.

In addition, unless clearly stated in the claims, the sequence of processing elements and sequences described in the present disclosure, the use of counts and letters, or the use of other names are not used to limit the sequence of processes and methods in the present disclosure. While the foregoing disclosure has discussed by way of various examples some embodiments of the invention that are presently believed to be useful, it should be understood that such detail is for illustrative purposes only and that the appended claims are not limited to the disclosed embodiments, but rather, the claims are intended to cover all modifications and equivalent combinations that fall within the spirit and scope of the embodiments of the present disclosure. For example, although the implementation of various components described above may be embodied in a hardware device, it may also be implemented as a software only solution, e.g., an installation on an existing server or mobile device.

In the same way, it should be noted that in order to simplify the expression disclosed in this disclosure and help the understanding of one or more embodiments of the invention, in the foregoing description of the embodiments of the present disclosure, sometimes multiple features are combined into one embodiment, drawings or descriptions thereof. This method of disclosure does not, however, imply that the subject matter of the disclosure requires more features than are recited in the claims. Rather, claimed subject matter may lie in less than all features of a single foregoing disclosed embodiment.

In some embodiments, counts describing the quantity of components and attributes are used. It should be understood that such counts used in the description of the embodiments use the modifiers “about”, “approximately” or “substantially” in some examples. Unless otherwise stated, “about”, “approximately” or “substantially” indicates that the stated figure allows for a variation of ±20%. Accordingly, in some embodiments, the numerical parameters used in the disclosure and claims are approximations that can vary depending upon the desired characteristics of individual embodiments. In some embodiments, numerical parameters should consider the specified significant digits and adopt the general digit retention method. Although the numerical ranges and parameters used in some embodiments of the present disclosure to confirm the breadth of the range are approximations, in specific embodiments, such numerical values are set as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

What is claimed is:

1. A semiconductor green laser, from bottom to top, comprising: a substrate, a lower limiting layer, a lower waveguide layer, an active layer, an upper waveguide layer, and an upper limiting layer, wherein,
the active layer is a quantum well composed of well layers and barrier layers, and a period of the quantum well is denoted as z, wherein 1≤z≤3;
each of the well layers includes any one of AlInGaN, AlInN, AlGaN, AlN, InN, InGaN, and GaN, or any combination thereof, and a thickness of each of the well layers is denoted as p, wherein 5 Å≤p≤100 Å;
each of the barrier layers includes any one of AlInGaN, AlInN, AlGaN, AlN, InN, InGaN, and GaN, or any combination thereof, and a thickness of each of the barrier layers is denoted as q, wherein 10 Å≤q≤200 Å; and
an electron effective mass of each of the well layers is less than an electron effective mass of each of the barrier layers, a spontaneous polarization coefficient of each of the well layers is less than a spontaneous polarization coefficient of each of the barrier layers, and a band gap of each of the well layers is less than a band gap of each of the barrier layers.

2. The semiconductor green laser of claim 1, wherein the active layer includes a first active layer and a second active layer, wherein
an electron effective mass of the first active layer has an inverted U-shaped distribution;
an electron effective mass of the second active layer has a W-shaped distribution;
a spontaneous polarization coefficient of the first active layer has an inverted U-shaped distribution;
a spontaneous polarization coefficient of the second active layer has a W-shaped distribution;
a band gap of the first active layer has an inverted U-shaped distribution; and
a band gap of the second active layer has a W-shaped distribution.

3. The semiconductor green laser of claim 2, wherein
the electron effective mass of the first active layer has a curvilinear distribution of a first function, the first function being denoted as y=Ax²+Bx+C (A<0);
the spontaneous polarization coefficient of the first active layer has a curvilinear distribution of a second function, the second function being denoted as y=Dx²+Ex+F (D<0); and
the band gap of the first active layer has a curvilinear distribution of a third function, the third function being denoted as y=Jx²+Kx+K (J<0), wherein
−500<A≤J≤D<0, and A, B, C, D, E, F, J, and K are constants.

4. The semiconductor green laser of claim 2, wherein
the electron effective mass of the second active layer has a curvilinear distribution of a fourth function, the fourth function being denoted as y=Lcos(Mx+N);
the spontaneous polarization coefficient of the second active layer (103b) has a curvilinear distribution of a fifth function, the fifth function being denoted as y=Pcos(Qx+O); and
the band gap of the second active layer (103b) has a curvilinear distribution of a sixth function, the sixth function being denoted as y=Rcos(Sx+T), wherein
P≤R≤L, and L, M, N, P, Q, O, R, S, T are constants.

5. The semiconductor green laser of claim 2, wherein
the electron effective mass of the first active layer is denoted as a, an electron effective mass of each of well layers of the second active layer is denoted as b, and an electron effective mass of each of barrier layers of the second active layer is denoted as c, wherein 0.05 mₑ≤b≤c≤a≤0.2 mₑ;
the spontaneous polarization coefficient of the first active layer is denoted as d, a spontaneous polarization coefficient of each of the well layers of the second active layer is denoted as e, and a spontaneous polarization coefficient of each of the barrier layers of the second active layer is denoted as f, wherein −0.05 C/m²≤e≤f≤d≤−0.02 C/m²; and
the band gap of the first active layer is denoted as g, a band gap of each of the well layers of the second active layer is denoted as h, and a band gap of each of the barrier layers of the second active layer is denoted as i, wherein 0.5eV≤h≤i≤g≤3.5 eV.

6. The semiconductor green laser of claim 2, wherein
an element concentration ratio In/Al of an element In to an element Al of the first active layer has a U-shaped distribution;
an element concentration ratio In/Al of an element In to an element Al of the second active layer has an M-shaped distribution; and
an element concentration ratio Si/H of an element Si to an element H of the first active layer has an inverted U-shaped distribution, and an element concentration ratio Si/H of an element Si to an element H of the second active layer has a linear distribution.

7. The semiconductor green laser of claim 6, wherein
the element concentration ratio In/Al of the first active layer is within a range of 10-100, the element concentration ratio In/Al of the second active layer is within a range of 1 E4-5E5, and an element concentration ratio In/Al of the second active layer to the first active layer is within a range of 1 E3-5E4.

8. The semiconductor green laser of claim 6, wherein
a descending angle of an element intensity of the element In in a direction from the second active layer to the first active layer is denoted as α, wherein 45°≤α90°;
a descending angle of an element intensity of the element In in a direction from the lower waveguide layer to the first active layer is denoted as β, wherein 45°≤β≤90°;
a descending angle of an element concentration ratio In/Al of the element In to the element Al in a direction from the second active layer to the first active layer is denoted as γ, wherein 35°≤γ≤90°; and
a descending angle of an element concentration ratio In/Al of the element In to the element Al in a direction from the lower waveguide layer to the first active layer is denoted as θ, wherein 35°≤θ≤90°; wherein
35°≤γ≤θ≤α≤β≤90°.

9. The semiconductor green laser of claim 1, wherein
the lower limiting layer includes any one of AlInGaN, AlInN, AlGaN, AlN, InN, InGaN, and GaN, or any combination thereof; and
the lower limiting layer includes a first lower limiting layer, a second lower limiting layer, a third lower limiting layer, a fourth lower limiting layer, and a fifth lower limiting layer.

10. The semiconductor green laser of claim 9, wherein
a thermal expansion coefficient of the first lower limiting layer is denoted as a1, a thermal expansion coefficient of the second lower limiting layer is denoted as a2, a thermal expansion coefficient of the third lower limiting layer is denoted as a3, a thermal expansion coefficient of the fourth lower limiting layer is denoted as a4, a thermal expansion coefficient of the fifth lower limiting layer is denoted as a5, a thermal expansion coefficient of the lower waveguide layer is denoted as b, a thermal expansion coefficient of the active layer is denoted as c, a thermal expansion coefficient of the upper waveguide layer is denoted as d, and a thermal expansion coefficient of the upper limiting layer is denoted as f; and
a gradient of a thermal expansion coefficient of the semiconductor green laser satisfies a relationship of: 2.5(10⁻⁶/K)≤c≤d≤a3≤b≤a5≤a1≤f≤a2≤a4≤6.5(10⁻⁶/K).

11. The semiconductor green laser of claim 9, wherein
a dielectric constant of the first lower limiting layer is denoted as g1, a dielectric constant of the second lower limiting layer is denoted as g2, a dielectric constant of the third lower limiting layer is denoted as g3, a dielectric constant of the fourth lower limiting layer is denoted as g4, a dielectric constant of the fifth lower limiting layer is denoted as g5, a dielectric constant of the lower waveguide layer is denoted as h, a dielectric constant of the active layer is denoted as i, a dielectric constant of the upper waveguide layer is denoted as j, and a dielectric constant of the upper limiting layer is denoted as k; and
a gradient of a dielectric constant of the semiconductor green laser satisfies a relationship of: 8≤g4≤g2≤k≤g1≤g5≤h≤g3≤j≤i≤12.

12. The semiconductor green laser of claim 9, wherein
an elastic coefficient C₃₃ of the first lower limiting layer is denoted as s1, an elastic coefficient C₃₃ of the second lower limiting layer is denoted as s2, an elastic coefficient C₃₃ of the third lower limiting layer is denoted as s3, an elastic coefficient C₃₃ of the fourth lower limiting layer is denoted as s4, an elastic coefficient C₃₃ of the fifth lower limiting layer is denoted as s5, an elastic coefficient C₃₃ of the third lower limiting layer is denoted as S3, an elastic coefficient C₃₃ of the lower waveguide layer is denoted as t, an elastic coefficient C₃₃ of the active layer is denoted as u, an elastic coefficient C₃₃ of the upper waveguide layer is denoted as v, and an elastic coefficient C₃₃ of the upper limiting layer is denoted as w; and
a gradient of an elastic coefficient C₃₃ of the semiconductor green laser satisfies a relationship of: 200 GPa≤u≤v≤s3≤t≤s4≤s2≤w≤s1≤s5≤450 GPa.

13. The semiconductor green laser of claim 9, wherein
a thermal expansion coefficient of the third lower limiting layer has a curvilinear distribution of a seventh function, the seventh function being denoted as y=x/sinx;
an elastic coefficient of the third lower limiting layer has a curvilinear distribution of an eighth function, the eighth function being denoted as y=x/sinx; and
a dielectric constant of the third lower limiting layer has a curvilinear distribution of a ninth function, the ninth function being denoted as y=Vx²+Ux+W(V<0), wherein V, U and W are constants.

14. The semiconductor green laser of claim 1, wherein
the lower waveguide layer includes any one of AlInGaN, AlInN, AlGaN, InGaN, InN, and GaN, or any combination thereof, and a thickness of the lower waveguide layer is within a range of 10 Å-9000 Å;
the upper waveguide layer includes any one of AlInGaN, AlInN, AlGaN, InGaN, InN, and GaN, or any combination thereof, and a thickness of the upper waveguide layer is within a range of 10 Å-9000 Å;
the upper limiting layer includes any one of AlInGaN, AlInN, AlN, AlGaN, InGaN, and GaN, or any combination thereof, and a thickness of the upper limiting layer is within a range of 10 Å-8000 Å;
the lower limiting layer includes any one of AlInGaN, AlInN, AlN, AlGaN, and GaN, or any combination thereof, and a thickness of the lower limiting layer is within a range of 10 Å-90,000 Å; and
the substrate includes any one of a sapphire, silicon, Ge, SiC, AlN, GaN, GaAs, InP, Mo, TiW, Cu, a sapphire/SiO₂ composite substrate, a sapphire/AlN composite substrate, a diamond, sapphire/SiNₓ, a sapphire/SiNₓ/SiO₂ composite substrate, a sapphire/SiO₂/SiNₓ composite substrate, and a magnesium aluminate spinel MgAl2O4, MgO, ZnO, ZrB2, LiAlO2, and LiGaO2 composite substrate.
